(19) United States
(12) Patent Application Publication
(10) Pub. No.: US 2013/0118779 A1
(43) Pub. Date: May 16, 2013

(54) CLEARANCE FILLING PRINTED CIRCUIT BOARD AND METHOD OF MANUFACTURING THE SAME

(71) Applicants: Duke Kyu LEE, Uiwang-si (KR); Chang Min IM, Pyeongtaek-si (KR); Sang Bum SIM, Gwangju-si (KR); Yun Kee CHO, Namyangju-si (KR); Hyun-Soo JEON, Gwangju-si (KR)

(72) Inventors: Duke Kyu LEE, Uiwang-si (KR); Chang Min IM, Pyeongtaek-si (KR); Sang Bum SIM, Gwangju-si (KR); Yun Kee CHO, Namyangju-si (KR); Hyun-Soo JEON, Gwangju-si (KR)

(21) Appl. No.: 13/416,029

(22) Filed: Mar. 9, 2012

(30) Foreign Application Priority Data
Nov. 14, 2011 (KR) 10-2011-0118256

(51) Int. Cl. H05K 1/02; H05K 3/22

(52) U.S. Cl. 174/250; 427/99.2

(57) ABSTRACT

A clearance filling PCB includes pin contact units on a surface of the external layer of the PCB and clearance filling units formed by molding a clearance between the pin contact units and polishing an insulating layer so that the height of the insulating layer becomes equal to the height of the pin contact units in order to prevent the sliding of a fine pitch circuit with a pin and induce accurate contact between the fine pitch circuit and the pin, and a method of manufacturing the same. The height of the insulating layer is made equal to the height of the pin contact units by molding the clearance between the pin contact units on the surface of the external layer of the PCB, and the sliding of a fine pitch circuit, requiring contacts, with a pin can be prevented.

### CROSS-REFERENCES TO RELATED APPLICATION

The present application claims the benefit of Korean Patent Application No. 10-2011-0118256 filed in the Korean Intellectual Property Office on Nov. 14, 2011, the entire contents of which are incorporated herein by reference.

### BACKGROUND OF THE INVENTION

1. Field of the Invention

The present invention relates to a clearance filling Printed Circuit Board (PCB) and a method of manufacturing the same and, more particularly, to a clearance filling PCB and a method of manufacturing the same, wherein the height of an insulating layer is made equal to the height of pads or patterns by molding a clearance between the pads or the patterns on a surface of the external layer of the PCB and the sliding of a fine pitch circuit, requiring contacts, with a pin can be prevented, accurate contact can be induced between the fine pitch circuit and the pin, and the fine pitch circuit can be closely adhered to other constituent elements (e.g., a socket and a stiffener) accurately by using a task of securing the cross-sectional area of the pad or the pattern through polishing.

2. Background of the Related Art

In general, in the fine pitch circuit specification, a failure in pin contact is frequently generated owing to the collapse (e.g., a round form) of a pad edge or a pattern edge. Several countermeasures were taken, but a perfect solution to the problem has not yet been proposed. That is, a solution to a characteristic failure due to the misalignment of pins is still insufficient.

The problem is described below with reference to FIGS. 1A and 1B.

That is, as shown in FIGS. 1A and 1B, the height of a pattern 101-1, 101-2 is not equal to the height of a clearance 102 which is a depressed portion between the patterns 101-1 and 101-2. For example, the height of the pattern 101-1 is higher than the height of the clearance 102.

Accordingly, there is a problem in that pins are misaligned owing to the collapse (e.g., a round form) of a pad edge or a pattern edge when the pin is contacted, as shown in FIG. 1B.

### SUMMARY OF THE INVENTION

Accordingly, the present invention has been made in view of the above problems occurring in the prior art, and it is an object of the present invention to provide a clearance filling PCB and a method of manufacturing the same, wherein the height of an insulating layer is made equal to the height of pads or patterns by molding a clearance between the pads or the patterns on a surface of the external layer of the PCB and the sliding of a fine pitch circuit, requiring contacts, with a pin can be prevented, accurate contact can be induced between the fine pitch circuit and the pin, and the fine pitch circuit can be closely adhered to other constituent elements (e.g., a socket and a stiffener) accurately by using a task of securing the cross-sectional area of the pad or the pattern through polishing.

To achieve the above object, a clearance filling Printed Circuit Board (PCB) according to an aspect of the present invention includes pin contact units formed on a surface of the external layer of the PCB and clearance filling units formed by molding a clearance between the pin contact units and polishing an insulating layer so that the height of the insulating layer becomes equal to the height of the pin contact units in order to prevent the sliding of a fine pitch circuit with a pin and induce accurate contact between the fine pitch circuit and the pin.

The pin contact units preferably are the patterns or pads of the PCB.

A method of manufacturing a clearance filling Printed Circuit Board (PCB) according to another aspect of the present invention includes the steps of forming pin contact units on a surface of the external layer of the PCB, coating plugging ink to cover the top of the PCB including the pin contact units, and forming clearance filling units for preventing the sliding of a fine pitch circuit with a pin and inducing accurate contact between the fine pitch circuit and the pin by polishing an insulating layer so that the height of the insulating layer formed of a clearance between the pin contact units coated with the plugging ink becomes equal to the height of the pin contact units.

### BRIEF DESCRIPTION OF THE DRAWINGS

Further objects and advantages of the invention can be more fully understood from the following detailed description taken in conjunction with the accompanying drawings in which:

FIG. 1A is a diagram showing a common PCB;

FIG. 1B is a diagram showing an aspect of a pin contact with a common pad or pattern;

FIG. 2 is a diagram showing a clearance filling PCB according to the present invention;

FIGS. 3A to 3C are processional flowcharts illustrating a method of manufacturing the clearance filling PCB according to the present invention; and

FIG. 4 is a diagram showing a state where the clearance filling PCB according to the present invention is used.

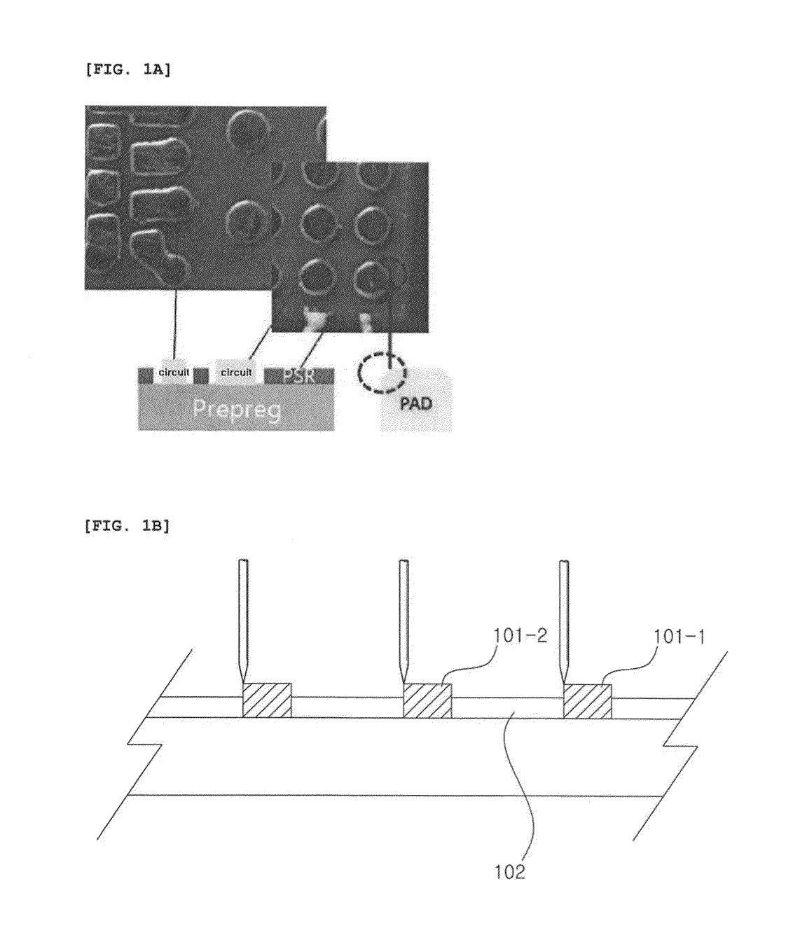

### DETAILED DESCRIPTION OF EMBODIMENTS

Embodiments of the present invention are illustrated in detail to the extent that those skilled in the art to which the present invention pertains are able to easily implement the present invention, but the scope of the present invention is not limited to the embodiments.

In order to clarify a description of the present invention, parts not related to the description are omitted, and the same reference numbers are used throughout the drawings to refer to the same or like parts.

In the specification and claims, when it is said that any element includes any element, it means the corresponding element does not exclude other elements other than the corresponding element and may further include other elements which fall within the scope of the technical spirit of the present invention.

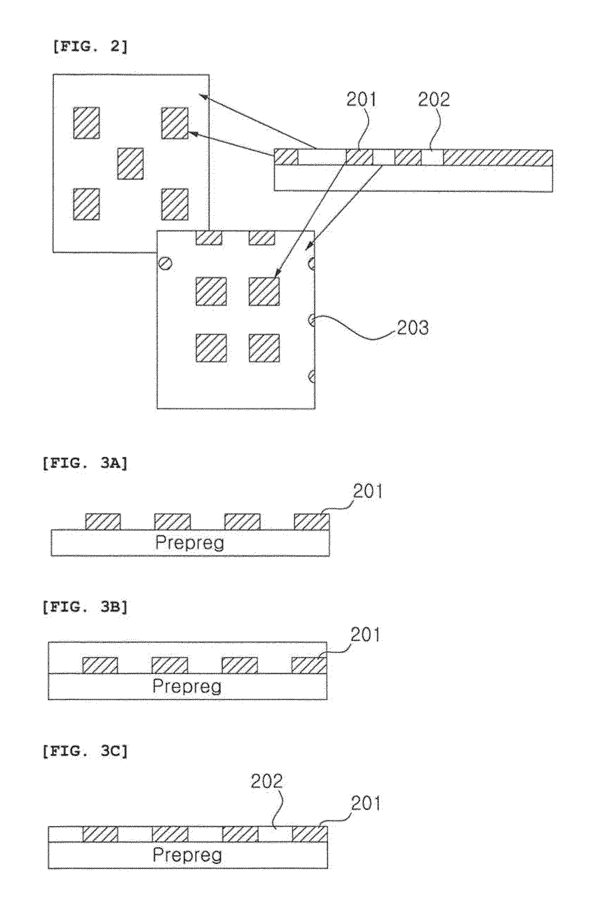

FIG. 2 is a diagram showing a clearance filling PCB according to the present invention.

As shown in FIG. 2, the clearance filling PCB according to the present invention chiefly includes pin contact units formed of patterns 201 or pads 203 on a surface of the external layer of the PCB and clearance filling units 202 each formed to have the same height as the pattern 201 or pad 203 between the patterns 201 or the pads 203 of the pin contact units.

That is, the clearance filling PCB according to the present invention includes the pin contact units formed of the patterns 201 or the pads 203 on a surface of the external layer of the PCB and the clearance filling units 202 formed by molding a clearance between the patterns 201 or the pads 203 and polishing the insulating layer so that the height of the insulating layer becomes equal to the height of the patterns 201 or the pads 203 so that the sliding of a fine pitch circuit with a pin can be prevented and accurate contact can be induced between the fine pitch circuit and the pin.

Here, the clearance filling units 202 are formed by coating the clearance between the patterns 201 or the pads 203 on the surface of the external layer of the PCB with plugging ink and then polishing the insulating layer so that the height of the patterns 201 or the pads 203 becomes equal to the height of the insulating layer. Accordingly, the sliding of a fine pitch circuit with a pin can be prevented and accurate contact can be induced between the fine pitch circuit and the pin. That is, the height of the insulating layer is made equal to the height of the patterns 201 or the pads 203 by molding the clearance between the patterns 201 or the pads 203 on the surface of the external layer of the PCB, and the sliding of a fine pitch circuit, requiring contacts, with a pin can be prevented and accurate contact can be induced between the fine pitch circuit and the pin by using a task of securing the cross-sectional area of the pad or the pattern through polishing.

The patterns 201 or the pads 203 are formed on the surface of the external layer of the PCB and are spaced apart from one another at specific intervals. The structure or form of the pattern may be modified in various ways depending on a desired printing form.

As described above, in the clearance filling PCB according to the present invention, the height of the insulating layer can be made equal to the height of the pads or patterns by molding the clearance between the pads or patterns on the surface of the external layer of the PCB. Furthermore, the sliding of a fine pitch circuit, requiring contacts, with a pin can be prevented, accurate contact can be induced between the fine pitch circuit and the pin, and the fine pitch circuit can be closely adhered to other constituent elements (e.g., a socket and a stiffener) accurately by using a task of securing the cross-sectional area of the pad or the pattern through polishing.

A method of manufacturing the clearance filling PCB of FIG. 2 according to the present invention (more particularly, a method of manufacturing the clearance filling units according to the present invention) is described below with reference to FIGS. 3A to 3C.

FIGS. 3A to 3C are processional flowcharts illustrating the method of manufacturing the clearance filling PCB according to an embodiment of the present invention. FIGS. 3A to 3C show examples in which the pin contact units are formed of the patterns.

As shown in FIGS. 3A to 3C, in order to manufacture the clearance filling PCB according to the present invention, first, the patterns 201 are formed on the surface of the external layer of the PCB. A method of forming the patterns is known in the art, and a detailed description thereof is omitted.

Next, the plugging ink is coated to cover the top of the PCB, including the patterns 201 formed on the surface of the external layer of the PCB.

Next, polishing is performed so that the height of the insulating layer formed of the clearance between the patterns 201 coated with the plugging ink becomes equal to the height of the patterns 201.

Accordingly, the clearance filling units 202 for preventing the sliding of a fine pitch circuit with a pin and inducing accurate contact between the fine pitch circuit and the pin are formed.

The patterns 201 are formed on the surface of the external layer of the PCB and spaced apart from one another at specific intervals. The structure or form of the pattern may be modified in various ways according to a desired printing form.

As described above, according to the present invention, the plugging ink is coated between the clearance between the pads or the patterns on the surface of the external layer of the PCB and then polished so that the height of the clearance become equal to the height of the pads or the patterns. Accordingly, the clearance filling units for preventing the sliding of a fine pitch circuit with a pin and inducing accurate contact between the fine pitch circuit and the pin are formed.

That is, the clearance filling units for making the height of the insulating layer equal to the height of the pads or the patterns by molding the clearance between the pads or the patterns on the surface of the external layer of the PCB and preventing the sliding of a fine pitch circuit, requiring contacts, with a pin and inducing accurate contact between the fine pitch circuit and the pin by using a task of securing the cross-sectional area of the pad or the pattern through polishing.

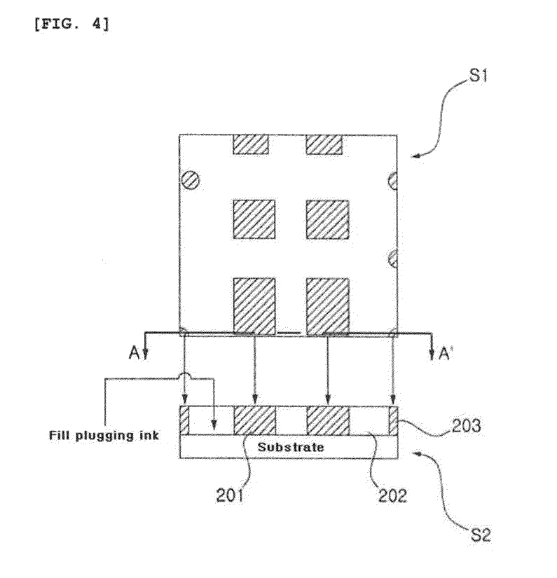

FIG. 4 is a diagram showing a state where the clearance filling PCB according to the present invention is used. In FIG. 4, a drawing indicated by ‘S1’ is a plan view seen at the top of the clearance filling PCB, and a drawing indicated by ‘S2’ is a cross-sectional view taken along line A-A′ of the clearance filling PCB of ‘S1’.

As shown in FIG. 4, the clearance filling PCB according to the present invention is formed by filling the clearance filling units 202 with plugging ink and then polishing the clearance filling units 202 so that the height of depressed portions (i.e., the clearance filling units 202) between the patterns 201 or the pads 203 becomes equal to the height of the patterns 201 or the pads 203.

That is, the clearance filling PCB according to the present invention is formed by filling the clearance filling units 202 (i.e., depressed portions) between the patterns 201 or the pads 203 with the plugging ink and then polishing the clearance filling units 202 so that the height of the clearance filling units 202 becomes equal to the height of the patterns 201 or the pads 203.

More particularly, the plugging ink is coated to cover the top of the PCB including the patterns 201 and the pads 203 formed on a surface of the external layer of the PCB. The clearance filling units 202 are formed by polishing the insulating layer formed of the depressed portions (i.e., the clearances) between the pads 203 or the patterns 201 coated with the plugging ink so that the height of the insulating layer becomes equal to the height of the patterns 201 or the pads 203.

As described above, the sliding of a fine pitch circuit, requiring contacts, with a pin can be prevented and accurate contact can be induced between the fine pitch circuit and the pin by means of a task of securing the cross-sectional area of the pad 203 or the pattern 201 through polishing.

Furthermore, accurate adhesion with other constituent elements (e.g., a socket and a stiffener) can be secured, and repair for a circuit deficit and circuit loss or a partial defect can be facilitated.

### DESCRIPTION OF REFERENCE NUMERALS OF PRINCIPAL ELEMENTS IN THE DRAWINGS

201: pattern
202: clearance filling unit
203: pad

What is claimed is:

1. A clearance filling Printed Circuit Board (PCB), comprising:
pin contact units formed on a surface of an external layer of the PCB; and
clearance filling units formed by molding a clearance between the pin contact units and polishing an insulating layer so that a height of the insulating layer becomes equal to a height of the pin contact units in order to prevent a sliding of a fine pitch circuit with a pin and induce accurate contact between the fine pitch circuit and the pin.

2. The clearance filling PCB according to claim 1, wherein the pin contact units are patterns or pads of the PCB.

3. A method of manufacturing a clearance filling Printed Circuit Board (PCB), comprising the steps of:
forming pin contact units on a surface of an external layer of the PCB;
coating plugging ink to cover a top of the PCB including the pin contact units; and
forming clearance filling units for preventing a sliding of a fine pitch circuit with a pin and inducing accurate contact between the fine pitch circuit and the pin by polishing an insulating layer formed of a clearance between the pin contact units coated with the plugging ink so that a height of the insulating layer becomes equal to a height of the pin contact units.

4. The method according to claim 3, wherein the pin contact units are formed of patterns or pads of the PCB.
